(19) United States
(12) Patent Application Publication
(10) Pub. No.: US 2025/0297404 A1
(43) Pub. Date: Sep. 25, 2025

(54) SINGLE CRYSTAL PULLING APPARATUS

(71) Applicant: SUMCO CORPORATION, Tokyo (JP)

(72) Inventors: Ryusuke YOKOYAMA, Tokyo (JP); Wataru SUGIMURA, Tokyo (JP)

(73) Assignee: SUMCO CORPORATION, Tokyo (JP)

(21) Appl. No.: 18/865,436

(22) PCT Filed: May 9, 2023
(86) PCT No.: PCT/JP2023/017427

§ 371 Date: Nov. 13, 2024

(30) Foreign Application Priority Data
May 19, 2022 (JP) 2022-082330

(51) Int. Cl. C30B 15/30; C30B 15/04; C30B 15/14; C30B 29/06; C30B 30/04

(52) U.S. Cl. CPC C30B 15/30; C30B 15/04; C30B 15/14; C30B 29/06; C30B 30/04

(57) ABSTRACT

There is provided a monocrystal pull-up apparatus, including: a chamber; a crucible disposed in the chamber to store a silicon melt; a pull-up unit that pulls up monocrystalline silicon and includes a pull-up shaft to which a seed crystal is attached at one end and a pull-up drive unit that rotates and vertically moves the pull-up shaft; a heat shield provided above the crucible to surround the monocrystalline silicon; and a magnetic-field applying unit configured to apply a horizontal magnetic field to the silicon melt in the crucible, in which a plurality of cuts are provided for a lower end of the heat shield such that the cuts are twofold symmetrical about the pull-up shaft.

### TECHNICAL FIELD

The present invention relates to a monocrystal pull-up apparatus for growing monocrystalline silicon.

### BACKGROUND ART

The Czochralski method is known as a method for producing monocrystalline silicon. In recent years, the so-called MCZ method has been widely used in which monocrystalline silicon is grown while a horizontal magnetic field is applied to a silicon melt.

In growing monocrystalline silicon by the MCZ method, the quality of the grown monocrystalline silicon, especially the oxygen concentration in the monocrystalline silicon, may vary even when monocrystalline silicon is grown under the same process conditions using the same monocrystal pull-up apparatus.

The following two factors may be responsible for the variation in oxygen concentration in growing monocrystalline silicon by the MCZ method.

The first factor is a rotation direction of the convection generated in the silicon melt by the application of the horizontal magnetic field (hereinafter referred to as a convection mode). The inventors have found out that, in the process in which solid polysilicon raw materials are fed and melted in a crucible and then monocrystalline silicon is pulled up while a horizontal magnetic field is applied, convection rotating from the bottom of the crucible toward a surface of the silicon melt is generated.

FIG. 1 schematically illustrates convection modes. A crucible 3 is viewed from an application direction of a horizontal magnetic field in FIG. 1. There are two convection modes: a mode in which a clockwise convection C1 predominates in the crucible 3 as illustrated in FIG. 1(a) (hereinafter referred to as a clockwise vortex mode) and a mode in which a counterclockwise convection C2 predominates in the crucible 3 as illustrated in FIG. 1(b) (hereinafter referred to as a counterclockwise vortex mode). In FIG. 1, a reference numeral MD indicates an application direction in a center portion of the horizontal magnetic field.

The second factor is the symmetry of structural objects that constitute the monocrystal pull-up apparatus.

The monocrystal pull-up apparatus is typically designed to be axially symmetrical about a pull-up shaft. This is because, it is more thermally stable for a system in which monocrystalline silicon and a crucible rotate to have the same rotation axis and an axisymmetric structure.

However, practical monocrystal pull-up apparatuses include structural objects that cannot be made axisymmetric, such as observation windows and electrodes of a heater that heats the crucible, and thus the monocrystal pull-up apparatus is not perfectly axisymmetric.

Oxygen eluted from the crucible during the pull-up of monocrystalline silicon is delivered to a solid-liquid interface during growth by the convection as described above, and is incorporated into the crystal. Here, if the monocrystal pull-up apparatus is perfectly axisymmetric and the process conditions are identical, the amount of oxygen incorporated into the crystal would not vary regardless of the convection mode.

However, the thermal environment is not uniform in practice because the monocrystal pull-up apparatus is not perfectly axisymmetric, which makes the amount of oxygen flux delivered in the clockwise vortex mode different from that in the counterclockwise vortex mode. As a result, the monocrystalline silicon is grown with different oxygen concentrations depending on the convection mode.

Even if monocrystalline silicon is grown using the same monocrystal pull-up apparatus under the same process conditions, different convection modes will produce crystals with different oxygen concentrations. This results in a lower yield of monocrystalline silicon produced.

Patent Literature 1 discloses a method for eliminating variation in oxygen concentration caused by convection modes by stably selecting one of two convection modes (clockwise vortex mode or counterclockwise vortex mode). Specifically, the convection mode is fixed to one of the two modes by actively biasing the heating capacity of a heater, thereby inhibiting the variation in oxygen concentration for each ingot of monocrystalline silicon.

Patent Literature 2 discloses a method of fixing a convection mode by biasing an inert gas flow between a heat shield and a surface of a silicon melt.

### CITATION LIST

### Patent Literature(s)

Patent Literature 1: JP 2019-151502 A

Patent Literature 2: JP 2019-151503 A

### SUMMARY OF THE INVENTION

### Problem(s) to be Solved by the Invention

However, in the method described in each of the above patent literatures, the convection mode is forcibly fixed, which makes the ambient thermal environment affecting the monocrystalline silicon to be pulled up uneven. As a result, the monocrystalline silicon is difficult to pull up stably.

An object of the invention is to provide a monocrystal pull-up apparatus capable of inhibiting variation in oxygen concentration for each ingot of monocrystalline silicon without fixing a convection mode.

### Means for Solving the Problem(s)

A monocrystal pull-up apparatus according to an aspect of the invention includes: a chamber; a crucible disposed in the chamber to store a silicon melt; a pull-up unit configured to pull up monocrystalline silicon, the pull-up unit including a pull-up shaft to which a seed crystal is attached at one end and a pull-up drive unit configured to rotate and vertically move the pull-up shaft; a heat shield provided above the crucible to surround the monocrystalline silicon; and a magnetic-field applying unit configured to apply a horizontal magnetic field to the silicon melt in the crucible, in which a plurality of cuts are provided for a lower end of the heat shield such that the cuts are twofold symmetrical about the pull-up shaft.

In the monocrystal pull-up apparatus, the chamber is preferably provided with a plurality of observation windows arranged to be twofold symmetrical about the pull-up shaft.

A monocrystal pull-up apparatus according to another aspect of the invention includes: a chamber; a crucible disposed in the chamber to store a silicon melt; a pull-up unit configured to pull up monocrystalline silicon, the pull-up unit including a pull-up shaft to which a seed crystal is attached at one end and a pull-up drive unit configured to rotate and vertically move the pull-up shaft; a heat shield provided above the crucible to surround the monocrystalline silicon; a magnetic-field applying unit configured to apply a horizontal magnetic field to the silicon melt in the crucible; and a plurality of observation windows provided for the chamber, in which the plurality of observation windows are arranged to be twofold symmetrical about the pull-up shaft.

Preferably, the monocrystal pull-up apparatus further includes a plurality of dopant feeders and the chamber is provided with a plurality of dopant inlets arranged to be twofold symmetrical about the pull-up shaft.

Preferably, the monocrystal pull-up apparatus further includes a cylindrical heat insulator provided along an inner surface of the chamber and a plurality of holes are provided for the heat insulator such that the holes are twofold symmetrical about the pull-up shaft.

In the monocrystal pull-up apparatus, the plurality of cuts are preferably aligned along an application direction in a center portion of the horizontal magnetic field.

### BRIEF EXPLANATION OF DRAWINGS

FIG. 1A schematically illustrates a convection mode.

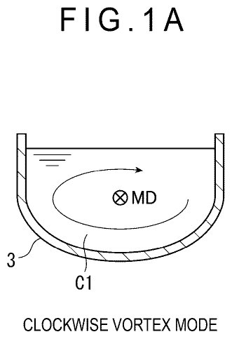

FIG. 1B schematically illustrates another convection mode.

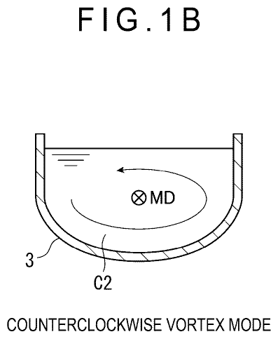

FIG. 2 is a schematic cross-sectional view of a monocrystal pull-up apparatus according to an exemplary embodiment of the invention.

FIG. 3 is a schematic plan view illustrating an arrangement of a magnetic-field applying unit, observation windows, and cuts of the monocrystal pull-up apparatus according to the exemplary embodiment of the invention.

FIG. 4A schematically illustrates a relationship between an inert gas flow and a convection flow.

FIG. 4B schematically illustrates another relationship between the inert gas flow and the convection flow.

FIG. 5 is a schematic cross-sectional view of a monocrystal pull-up apparatus according to a modified example of the invention.

FIG. 6 is a schematic plan view illustrating an arrangement of the magnetic-field applying unit, the observation windows, and the cuts of the monocrystal pull-up apparatus according to the modified example of the invention.

FIG. 7 is a schematic plan view illustrating arrangements of the observation window(s) and the cut(s) of the monocrystal pull-up apparatuses in Examples and Comparative.

### DESCRIPTION OF EMBODIMENT(S)

### Background to the Invention

As described above, if a monocrystal pull-up apparatus is perfectly axisymmetric, ingots of monocrystalline silicon will have the same amount of oxygen incorporated thereinto regardless of the convection mode. The perfectly axisymmetric structure, however, is not achievable due to the presence of a structural object(s) that cannot be made axisymmetric.

To design a structure of a monocrystal pull-up apparatus that inhibits a quality difference in ingots of monocrystalline silicon due to the convection mode, the inventors examined the effect of a static magnetic field on a silicon melt.

The effect of the static magnetic field on the silicon melt, or Lorentz force, is identical regardless of whether the magnetic field direction is positive or negative. Let B be the magnetic field, j be the induced current, and F be the Lorentz force (B, j, and F are all vectors), then F=j×B (cross product).

If the magnetic field B′=−B is applied, the induced current j′ is j′=−j. The Lorentz force F′ is F′=j′×B′=−j×−B=j×B=F, and F and F′ are identical. Thus, the entire system including the magnetic field is twofold symmetrical (180-degree rotational symmetry).

The above indicates that if the structure of the monocrystal pull-up apparatus is twofold symmetrical about a pull-up shaft, the effects of the apparatus and the magnetic field on the silicon melt will not vary regardless of whether the convection mode is a clockwise vortex mode or a counterclockwise vortex mode. In other words, it is believed that the twofold symmetrical structure of the monocrystal pull-up apparatus can inhibit the variation in oxygen concentration.

### Configuration of Monocrystal Pull-Up Apparatus

A configuration of a monocrystal pull-up apparatus according to an embodiment of the invention will be described.

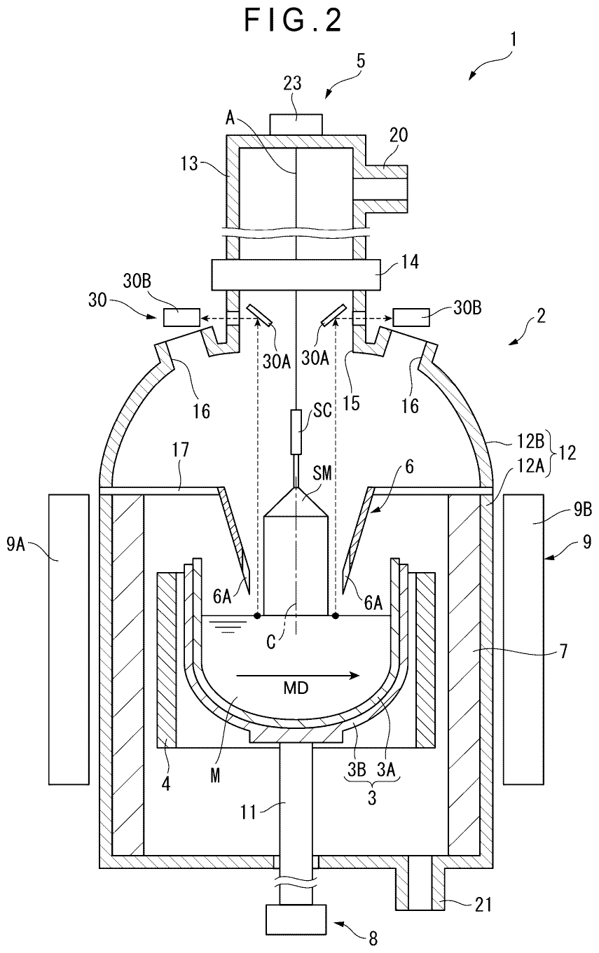

As illustrated in FIG. 2, a monocrystal pull-up apparatus 1, which is an apparatus for pulling up monocrystalline silicon SM by the MCZ method, includes: a chamber 2; a crucible 3 arranged in the chamber 2 to store a silicon melt M; a heater 4; a pull-up unit 5 for pulling up the monocrystalline silicon SM; a heat shield 6 provided above the crucible 3 to surround the monocrystalline silicon SM; a heat insulator 7 provided along an inner surface of the chamber 2; a crucible driver 8; and a magnetic-field applying unit 9 for applying a horizontal magnetic field to the silicon melt M.

The crucible 3 has a double structure including a quartz crucible 3A and a graphite crucible 3B that houses the quartz crucible 3A.

The crucible driver 8 has a support shaft 11 that supports the crucible 3 from below. The crucible driver 8 rotates and vertically moves the crucible 3 at a predetermined speed.

The chamber 2 includes a main chamber 12 and a pull chamber 13 connected to an upper part of main chamber 12. The main chamber 12 and the pull chamber 13 are connected via a gate valve 14.

The main chamber 12 includes a body 12A in which the crucible 3, heater 4, heat shield 6, and the like are arranged, and a cover 12B that covers an upper surface of the body 12A. The cover 12B has an opening 15 through which an inert gas such as argon gas is introduced into the main chamber 12 and a pair of observation windows 16 made of quartz through which the interior of the chamber 2 is observed using an optical observation means or the like. A support portion 17 provided between the body 12A and the cover 12B extends inward.

A gas inlet 20, through which an inert gas is introduced into the main chamber 12, is provided for the pull chamber 13. A gas outlet 21 is provided at a lower part of the body 12A of the main chamber 12. The gas in the main chamber 12 sucked by driving an unillustrated vacuum pump is discharged from the gas outlet 21.

The inert gas introduced into the chamber 2 through the gas inlet 20 flows downward between the growing monocrystalline silicon SM and the heat shield 6. The inert gas then flows into a space between a lower end of the heat shield 6 and a liquid surface of the silicon melt M, and flows toward the outside of the heat shield 6 and the outside of the crucible 3. Thereafter, the inert gas flows downward along the outside of the crucible 3, to be discharged from the gas outlet 21.

The heater 4 is of a resistance heating type and is disposed around the crucible 3.

The heat insulator 7 is formed to be cylindrical and provided outside the heater 4 along the inner surface of the chamber 2.

The pull-up unit 5 includes a pull-up shaft A to which the seed crystal SC is attached at one end, and a pull-up drive unit 23 that rotates and vertically moves the pull-up shaft A.

The heat shield 6 shields the growing monocrystalline silicon SM from high temperature radiation heat from the silicon melt M in the crucible 3, the heater 4, and a side wall of the crucible 3. The heat shield 6 inhibits outward heat diffusion from a solid-liquid interface that is an interface on which crystal grows and a vicinity thereof, thus controlling a vertical temperature gradient of a center portion and an outer peripheral portion of the monocrystalline silicon SM.

In addition, the heat shield 6 functions as a flow straightening cylinder through which evaporation substances from the silicon melt M are exhausted to the outside of the furnace by an inert gas introduced from above the furnace.

An upper end of the heat shield 6 is supported by the support portion 17 of the chamber 2. The heat shield 6 is formed in the shape of a circular truncated cone whose diameter decreases toward its lower end.

A pair of cuts 6A is formed at the lower end of the heat shield 6. The cuts 6A make it possible to purposefully create a distribution in the flow of the inert gas flowing over the silicon melt M. In other words, the cuts 6A can vary the flow rate of the inert gas flowing between the monocrystalline silicon SM and the heat shield 6 in a circumferential direction. The arrangement of the cuts 6A will be described later.

The shape of the heat shield 6 is not limited to the shape described above. For example, the heat shield 6 may have the shape of a circular truncated cone including a cylindrical body and a flange-shaped protrusion that protrudes inward from the entire lower end of the body, the diameter of the protrusion decreasing toward its lower end.

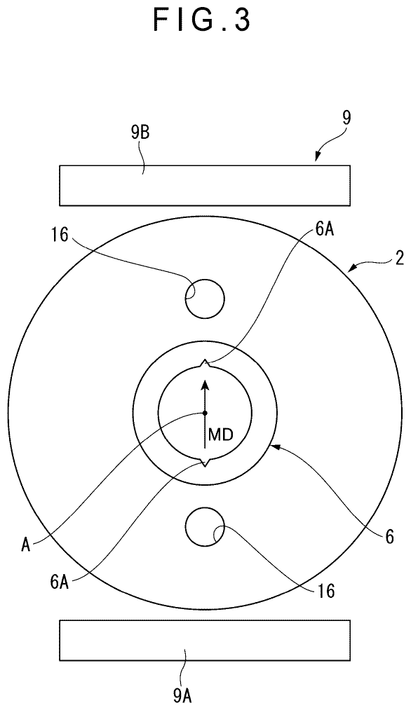

FIG. 3 is a schematic plan view illustrating an arrangement of the magnetic-field applying unit 9, the pair of observation windows 16, and the pair of cuts 6A. To describe the arrangement, the illustration of FIG. 3 is simplified, for example, the chamber 2 is illustrated only in outline.

As illustrated in FIG. 3, the magnetic-field applying unit 9 includes a first magnetic body 9A and a second magnetic body 9B each in the form of an electromagnetic coil. The first and second magnetic bodies 9A and 9B are provided outside the chamber 2 in such a manner as to be opposed to each other with the crucible 3 (see FIG. 2) interposed therebetween. The above arrangement of the magnetic-field applying unit 9 makes an application direction MD in a center portion of the magnetic field horizontal, the application direction MD passing through a center axis C of the crucible 3. That is, the center portion of the magnetic field is in a horizontal direction passing through the center axis C of the crucible 3.

The paired cuts 6A are formed to be twofold symmetrical about the pull-up shaft A. The two cuts 6A formed as a pair are aligned along the application direction MD of the magnetic field. In other words, one of the cuts 6A is disposed at an upstream side in the application direction MD of the magnetic field and the other of the cuts 6A is disposed at a downstream side in the application direction MD of the magnetic field in such a manner that the two cuts 6A are farthest apart.

Similar to the cuts 6A, the paired observation windows 16 are formed to be twofold symmetrical about the pull-up shaft A. The two observation windows 16 formed as a pair are aligned along the application direction MD of the magnetic field.

It is not indispensable for the twofold symmetry to be exactly 180-degree rotational symmetry, and 180±2-degree rotational symmetry is acceptable.

It is not indispensable for the center axis C of the heat shield 6 (see FIG. 2) to be perfectly aligned with the center axis of the pull-up shaft A, and the center axis C may be displaced horizontally by up to 2.5 mm in either direction. The heater 4, the heat insulator 7, and the body 12A of the chamber 2 may likewise be displaced horizontally by up to 2.5 mm in either direction.

In producing monocrystalline silicon SM with the use of the monocrystal pull-up apparatus 1, all silicon materials are melted in the absence of a magnetic field, and once all the silicon materials are melted, a horizontal magnetic field is applied to restrain the movement of convection and the monocrystalline silicon SM is pulled up.

The inert gas fed from the gas inlet 20 (see FIG. 2) is supplied to a surface of the silicon melt M and flows along the surface of the silicon melt M toward the outside of the crucible 3. Since the cuts 6A enlarge a space, the flow rate of the inert gas flowing through the space created by the cuts 6A increases.

When the pull-up of the monocrystalline silicon SM reaches a tail thereof, the application of the horizontal magnetic field is stopped and the pull-up of the monocrystalline silicon SM is completed.

The application of the horizontal magnetic field may be started before the melting of the silicon materials. That is, the application of a horizontal magnetic field may be started either before or after the melting of the silicon materials.

According to the above exemplary embodiment, the structure of the monocrystal pull-up apparatus 1 is twofold symmetrical by arranging the pair of observation windows 16 and the pair of cuts 6A to be twofold symmetrical about the pull-up shaft A. As described above, in the monocrystal pull-up apparatus 1 of which structure is twofold symmetrical about the pull-up shaft A, the effects of the apparatus and the magnetic field on the silicon melt M do not vary irrespective of the convection mode, thereby making it possible to inhibit the variation in oxygen concentration.

In addition, if multiple monocrystal pull-up apparatuses are produced and monocrystalline silicon is pulled up in each apparatus, variation in oxygen concentration between the apparatuses can be inhibited.

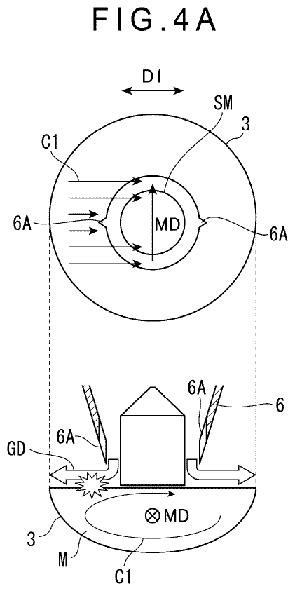

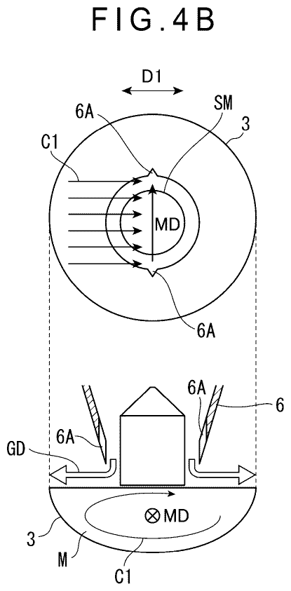

The flow rate of the inert gas flowing through the space created by the cuts 6A is large. Thus, when the cuts 6A formed as a pair are aligned along a horizontal direction D1 orthogonal to the application direction MD in a center portion of the horizontal magnetic field, an inert gas GD with a large flow rate collides with a convection C1 flowing over the liquid surface of the silicon melt M, thereby affecting the flow of the convection C1, as illustrated in FIG. 4A.

In the arrangement of the pair of cuts 6A aligned along the application direction MD in the center portion of the horizontal magnetic field according to the exemplary embodiment, the flow of convection C1 does not collide with the inert gas GD with a large flow rate, as illustrated in FIG. 4B. Such an arrangement of the cuts 6A can reduce the effect on the flow over the surface of the silicon melt M.

In the above exemplary embodiment, the cuts 6A are aligned along the application direction MD in the center portion of the horizontal magnetic field. The invention, however, is not limited thereto. The cuts 6A may be aligned, for example, along a direction orthogonal to the application direction MD in the center portion of the horizontal magnetic field, as long as such an arrangement has no effect on the flow over the surface of the silicon melt M. Similarly, it is not indispensable to align the observation windows 16 along the application direction MD of the horizontal magnetic field.

The monocrystal pull-up apparatus 1 of the exemplary embodiment has a twofold symmetrical structure including the pair of observation windows 16 and the pair of cuts 6A. The apparatus, however, may have a twofold symmetrical structure including only the pair of observation windows 16 without the pair of cuts 6A. If cuts 6A are additionally provided for such an apparatus, the cuts 6A are preferably arranged to be twofold symmetrical.

Likewise, the apparatus may have a twofold symmetrical structure including only the pair of cuts 6A without the pair of observation windows 16.

The pair of cuts 6A and the pair of observation windows 16 are provided in the exemplary embodiment. The invention, however, is not limited thereto. Multiple cuts 6A and multiple observation windows 16 (e.g., four cuts 6A and four observation windows 16) may be provided as long as the apparatus has a twofold symmetrical structure.

### MODIFIED EXAMPLES

Subsequently, modified examples of the monocrystal pull-up apparatus will be described.

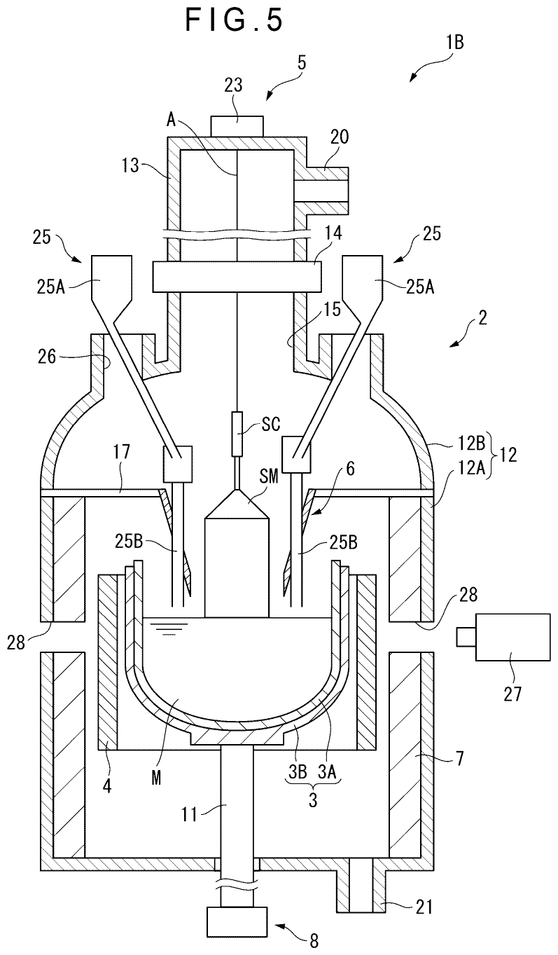

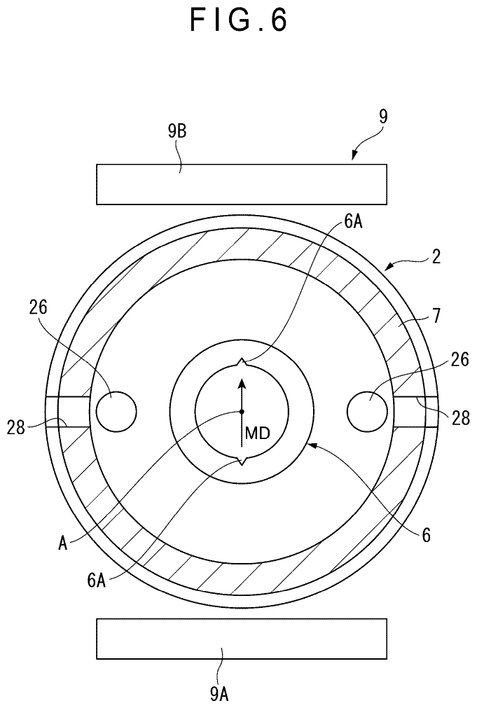

As illustrated in FIGS. 5 and 6, a monocrystal pull-up apparatus 1B according to a modified example includes dopant feeders 25 by which a dopant is additionally supplied. The dopant feeder 25, which includes a dopant holder 25A and a dopant dropping pipe 25B, allows the dopant to be charged and dropped even during the operation of the apparatus 1B. The dopant dropping pipes 25B are inserted into the chamber 2 through dopant inlets 26.

In the monocrystal pull-up apparatus 1B according to the modified example, the dopant inlets 26 are provided as a pair to be twofold symmetrical about the pull-up shaft A.

Two dopant feeders 25 are provided in this modified example. However, it is not indispensable to supply the dopant using both of the dopant feeders 25. The dopant may be fed using only one of the dopant feeders 25.

The monocrystal pull-up apparatus 1B according to the modified example also includes a temperature measurement device 27. The temperature measurement device 27 measures a temperature inside the chamber 2 through a hole 28 formed in the chamber 2 and the heat insulator 7.

In the monocrystal pull-up apparatus 1B according to the modified example, holes 28 are formed as a pair to be twofold symmetrical about the pull-up shaft A.

The structural object(s) that may affect the uniformity of the thermal environment should have a twofold symmetrical structure, as described above.

### Examples and Comparative

Subsequently, Examples and Comparative of the invention will be described. In Examples and Comparative, multiple ingots of monocrystalline silicon were pulled up using a monocrystal pull-up apparatus as described with reference to FIG. 2, etc. Specifically, 400 kg of polysilicon raw materials were fed into a 32-inch diameter crucible and melted, and then monocrystalline silicon of 300 mm in diameter was pulled up under the same process conditions. In doing so, a temperature measurement unit 30 (see FIG. 2) was used to determine the convection mode.

The temperature measurement unit 30, which includes a pair of reflectors 30A and a pair of radiation thermometers 30B, measures a temperature of a surface of the silicon melt M.

### Comparative 1

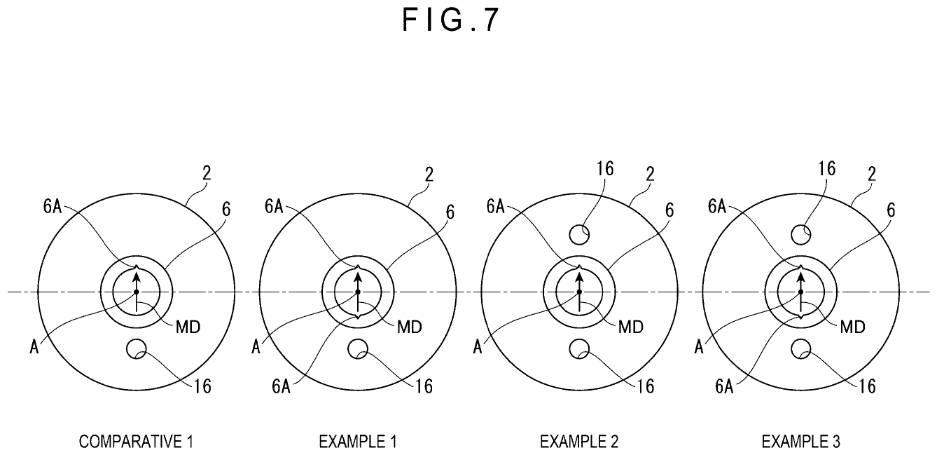

FIG. 7 is a schematic plan view illustrating arrangements of the observation window(s) and the cut(s) of the monocrystal pull-up apparatuses in Examples and Comparative.

As illustrated in FIG. 7, the monocrystal pull-up apparatus in Comparative 1 is provided with one observation window 16 and one cut 6A in the heat shield 6. Thus, the observation window 16 and cut 6A in Comparative 1 are not arranged to be twofold symmetrical.

Specifically, the observation window 16 of Comparative 1 is, viewed from above, disposed only on an upstream side in the application direction MD of the magnetic field passing through the pull-up shaft A. The cut 6A in Comparative 1 is disposed only on a downstream side in the application direction MD of the magnetic field.

### Example 1

As illustrated in FIG. 7, the monocrystal pull-up apparatus in Example 1 is provided with one observation window 16. Further, in the monocrystal pull-up apparatus in Example 1, the heat shield 6 has two cuts 6A arranged to be twofold symmetrical about the pull-up shaft A.

Specifically, the observation window 16 in Example 1 is disposed only on the upstream side in the application direction MD of the magnetic field. The cuts 6A in Example 1 are respectively disposed on the upstream and downstream sides in the application direction MD of the magnetic field.

### Example 2

As illustrated in FIG. 7, in the monocrystal pull-up apparatus in Example 2, two observation windows 16 are arranged to be twofold symmetrical about the pull-up shaft A. Further, in the monocrystal pull-up apparatus in Example 2, the heat shield 6 has one cut 6A.

Specifically, the observation windows 16 in Example 2 are respectively disposed on the upstream and downstream sides in the application direction MD of the magnetic field. The cut 6A in Example 2 is disposed only on the downstream side in the application direction MD of the magnetic field.

### Example 3

As illustrated in FIG. 7, in the monocrystal pull-up apparatus in Example 3, two observation windows 16 are arranged to be twofold symmetrical about the pull-up shaft A. Further, in the monocrystal pull-up apparatus in Example 2, the heat shield 6 has two cuts 6A arranged to be twofold symmetrical about the pull-up shaft A.

Specifically, the observation windows 16 in Example 3 are respectively disposed on the upstream and downstream sides in the application direction MD of the magnetic field. The cuts 6A in Example 3 are respectively disposed on the upstream and downstream sides in the application direction MD of the magnetic field.

### Evaluation

In Comparative and Examples described above, evaluation was performed on the difference between the oxygen concentration of wafers cut from ingots of monocrystalline silicon pulled up in the clockwise vortex mode and the oxygen concentration of wafers cut from ingots of monocrystalline silicon pulled up in the counterclockwise vortex mode.

Five ingots of monocrystalline silicon were pulled up in the clockwise vortex mode and the counterclockwise vortex mode, respectively, and wafers were cut out at a position 500 mm below the top of the monocrystalline silicon and the oxygen concentration was measured.

Specifically, the difference between the average oxygen concentration of five wafers in the clockwise vortex mode and the average oxygen concentration of five wafers in the counterclockwise vortex mode was evaluated in percent (%) of the average oxygen concentration of all (10) wafers. That is, an evaluation index a can be represented by the following numerical formula (1).

$$\begin{matrix}Numerical Formula 1 & \\ α = \frac{\vert \frac{1}{5} {\sum }_{n = 1}^{5} {[ O i ]}_{n}^{clockwise vortex} - \frac{1}{5} {\sum }_{n = 1}^{5} {[ O i ]}_{π}^{counterclockwise vortex} \vert}{\frac{1}{10} {\sum }_{n = 1}^{10} {[ O i ]}_{π}} \times 100 & ( 1 )\end{matrix}$$

The evaluation index α represents the difference in oxygen concentration between the clockwise vortex mode and the counterclockwise vortex mode. A larger a means a larger difference in oxygen concentration, i.e., a larger variation in oxygen concentration between batches.

TABLE 1

| | Evaluation |
|---|---|
| | indexα |
| | (%) |
| Comp. 1 | 16 |
| Ex. 1 | 10 |
| Ex. 2 | 6 |
| Ex. 3 | 0 |

As shown in Table 1, making the observation windows 16 or cuts 6A twofold symmetrical reduced the difference in oxygen concentration between the clockwise vortex mode and the counterclockwise vortex mode. Especially, in Example 3, where the observation windows 16 and cuts 6A were made twofold symmetrical, the difference in oxygen concentration between the clockwise vortex mode and the counterclockwise vortex mode was eliminated, resulting in ingots of monocrystalline silicon of equal quality.

Further, Example 1 where only the cuts were made twofold symmetrical had a smaller difference in oxygen concentration between the clockwise vortex mode and the counterclockwise vortex mode than Comparative 1 using a conventional structure.

Furthermore, Example 2 where only the observation windows were made twofold symmetrical had a smaller difference in oxygen concentration between the clockwise vortex mode and the counterclockwise vortex mode than Example 1. This revealed that the twofold symmetrical structure of the observation windows was more effective than the twofold symmetrical structure of the cuts.

Based on the above, it was shown that the batch-to-batch variation in oxygen concentration can be reduced by making the observation windows or the cuts twofold symmetrical in the monocrystal pull-up apparatus.

### EXPLANATION OF CODES

1 . . . monocrystal pull-up apparatus, 2 . . . chamber, 3 . . . crucible, 5 . . . pull-up unit, 6 . . . heat shield, 6A . . . cut, 7 . . . heat insulator, 9 . . . magnetic-field applying unit, 16 . . . observation window, 23 . . . pull-up drive unit, 25 . . . dopant feeder, 26 . . . dopant inlet, 28 . . . hole, A . . . pull-up shaft, M . . . silicon melt, SC . . . seed crystal, SM . . . monocrystalline silicon.

1. A monocrystal pull-up apparatus, comprising:
a chamber;
a crucible disposed in the chamber to store a silicon melt;
a pull-up unit configured to pull up monocrystalline silicon, the pull-up unit comprising a pull-up shaft to which a seed crystal is attached at one end and a pull-up drive unit configured to rotate and vertically move the pull-up shaft;
a heat shield provided above the crucible to surround the monocrystalline silicon; and
a magnetic-field applying unit configured to apply a horizontal magnetic field to the silicon melt in the crucible, wherein
a plurality of cuts are provided for a lower end of the heat shield such that the cuts are twofold symmetrical about the pull-up shaft.

2. The monocrystal pull-up apparatus according to claim 1, wherein
the chamber is provided with a plurality of observation windows arranged to be twofold symmetrical about the pull-up shaft.

3. A monocrystal pull-up apparatus, comprising:
a chamber;
a crucible disposed in the chamber to store a silicon melt;
a pull-up unit configured to pull up monocrystalline silicon, the pull-up unit comprising a pull-up shaft to which a seed crystal is attached at one end and a pull-up drive unit configured to rotate and vertically move the pull-up shaft;
a heat shield provided above the crucible to surround the monocrystalline silicon;
a magnetic-field applying unit configured to apply a horizontal magnetic field to the silicon melt in the crucible; and
a plurality of observation windows provided for the chamber, wherein
the plurality of observation windows are arranged to be twofold symmetrical about the pull-up shaft.

4. The monocrystal pull-up apparatus according to claim 1, further comprising a plurality of dopant feeders, wherein
the chamber is provided with a plurality of dopant inlets arranged to be twofold symmetrical about the pull-up shaft.

5. The monocrystal pull-up apparatus according to claim 1, further comprising a cylindrical heat insulator provided along an inner surface of the chamber, wherein
a plurality of holes are provided for the heat insulator such that the holes are twofold symmetrical about the pull-up shaft.

6. The monocrystal pull-up apparatus according to claim 2, wherein
the plurality of cuts are aligned along an application direction in a center portion of the horizontal magnetic field.

7. The monocrystal pull-up apparatus according to claim 3, further comprising a plurality of dopant feeders, wherein
the chamber is provided with a plurality of dopant inlets arranged to be twofold symmetrical about the pull-up shaft.

8. The monocrystal pull-up apparatus according to claim 3, further comprising a cylindrical heat insulator provided along an inner surface of the chamber, wherein
a plurality of holes are provided for the heat insulator such that the holes are twofold symmetrical about the pull-up shaft
